(19) United States
(12) Patent Application Publication
(10) Pub. No.: US 2004/0164391 A1
(43) Pub. Date: Aug. 26, 2004

(54) Stacked semiconductor device

(76) Inventor: Toru Okamura, Hyogo (JP)

Correspondence Address: MCDERMOTT WILL & EMERY LLP, 600 13TH STREET, N.W., WASHINGTON, DC, 20005-3096, US

(21) Appl. No.: 10/626,882

(22) Filed: Jul. 25, 2003

(30) Foreign Application Priority Data
Jul. 25, 2002 (JP) 2002-216913

(51) Int. Cl. H01L 23/02

(52) U.S. Cl. 257/686

(57) ABSTRACT

A stacked semiconductor device has a plurality of semiconductor elements mounted on the device in a stacked form. Each semiconductor element has a rectangular upper surface. A plurality of electrode pads is provided on the rectangular upper surface of the semiconductor element. In each semiconductor element, the electrode pads are arranged near two adjacent sides of the rectangular upper surface. A space for performing wire connection is made between two adjacent semiconductor elements. The adjacent semiconductor elements are joined to each other only by a die-bonding material without using any dummy element. The stacked semiconductor device can have increased number of electrode pads and increased functions compared to a conventional stacked semiconductor device.

### BACKGROUND OF THE INVENTION

1. Field of the Invention

The present invention relates to a thin stacked semiconductor device in which a plurality of semiconductor elements are mounted in a stacked form.

2. Description of the Prior Art

A semiconductor device of a semiconductor-element-stacked type (simply referred to as “stacked semiconductor device”) is widely used in recent years. In the stacked semiconductor device, a plurality of semiconductor elements are mounted in a stacked form in order to increase the mounting density of the semiconductor elements (e.g. semiconductor chips) so as to improve the operating throughput or storing capacity of the device, or to downsize the device. In the conventional stacked semiconductor device, in order to stack and mount a plurality of same-size (i.e. same-shape) semiconductor elements on the device, it is necessary to provide a space for performing wire connection between two semiconductor elements adjacent to each other in the stacking direction.

FIGS. 4A to 4C show an example of a conventional stacked semiconductor device in which a plurality of same-size semiconductor elements are stacked. As shown in FIG. 4A, in the conventional stacked semiconductor device, on a rectangular or square surface of a semiconductor element 101, a plurality of electrode pads 102 are arranged in a line near each of two opposite sides of the rectangular or square surface. As shown in FIGS. 4B and 4C, wire-connecting portions 103 for connecting the electrode pads 102 with wires 109 are formed on the electrode pads 102. In the device, each of the semiconductor elements 101 has such a structure that a wiring layer 107 and a silicon-nitride film 108 (protective layer) are stacked in turn on a silicon substrate 106 (i.e. Si substrate). The lower surface or back surface of the electrode pad 102 is connected to the wiring layer 107 while the upper surface of the electrode pad 102 is exposed to the outside.

In the conventional semiconductor device, a dummy element 104 (silicon spacer) is disposed between the two semiconductor elements 101 adjacent to each other in the stacking direction in order to make a space for performing wire connection. The dummy element 104 is joined to the semiconductor elements 101 by means of die-bonding materials 105. Thus, in the conventional stacked semiconductor device in which the same-size semiconductor elements 101 are stacked, because the dummy element 104 is disposed between the semiconductor elements 101, there is such a problem that the whole height or thickness of the stacked semiconductor device increases so that it is impossible to sufficiently downsize the device.

Japanese Laid-Open Patent Publication No. 6-244360 discloses a stacked semiconductor device whose whole height or thickness is decreased by forming a step at peripheral portion of each of same-size stacked semiconductor elements so as to secure a space for performing wire connection without using any dummy element. However, the conventional stacked semiconductor device has such a problem that the fabrication process thereof is complicated because the process of forming the step on the semiconductor element is required. In addition, there is such a problem that because the semiconductor element requires a thickness capable of withstanding formation of the step, it is impossible to use a thin semiconductor element so as to sufficiently decrease the whole height or thickness of the stacked semiconductor device.

### SUMMARY OF THE INVENTION

The present invention, which has been achieved to solve the above-mentioned conventional problems, has an object to provide a stacked semiconductor device whose whole height or thickness is decreased and which can be sufficiently downsized, even if a plurality of same-size semiconductor elements are stacked therein.

A stacked semiconductor device according to the present invention mounts stacked semiconductor elements respectively having a quadrangular surface on which a plurality of electrode pads (i.e. wiring pads) are provided. In the device, electrode pads on each semiconductor element are intensively arranged near two sides adjacent to each other, of the quadrangular surface. The semiconductor elements adjacent to each other in the stacking direction are shifted to each other in the direction parallel with the quadrangular surfaces of the semiconductor elements so that the electrode pads of each semiconductor element do not overlap with the other semiconductor element when viewed from the direction orthogonal to the quadrangular surfaces of the semiconductor elements.

In the stacked semiconductor device, when a plurality of same-size semiconductor elements are stacked, a space is formed near an electrode pad without inserting any dummy element between the semiconductor elements. In consequence, it is possible to easily perform wire connection or connect the wire to the electrode pad. Therefore, it is possible to decrease the whole height or thickness of the stacked semiconductor device and downsize the stacked semiconductor device.

Alternatively, in the stacked semiconductor device, the surfaces of the adjacent semiconductor elements on which the electrode pads are provided may be faced to each other, or the electrode pads may be arranged on the side surfaces of the semiconductor elements. In any of the stacked semiconductor devices, it is preferable that the semiconductor elements adjacent to each other in the stacking direction are directly bonded by means of an adhesive such as a die-bonding agent, in order to decrease the height or thickness of the semiconductor device. In this case, it is possible to almost minimize the height or thickness of the stacked semiconductor device because the whole height or thickness of the stacked semiconductor device becomes only slightly larger than the total thickness of the semiconductor elements.

Regarding that, each of Japanese Laid-Open Patent Publications Nos. 2001-217383, 2001-298150 and 2000-156464 discloses a stacked semiconductor device in which semiconductor elements are stacked without using any dummy element. However, any of the conventional stacked semiconductor devices does not have such features of the stacked semiconductor devices according to the present invention as a feature that the electrode pads are intensively arranged near the sides adjacent to each other of the quadrangular surface, a feature that the surfaces on which the electrode pads are provided are faced to each other, and a feature that the electrode pads are arranged on the side surfaces of the semiconductor elements.

### BRIEF DESCRIPTION OF THE DRAWINGS

Various characteristics and advantages of the present invention will become clear from the following description taken in conjunction with the preferred embodiments with reference to the accompanying drawings, in which:

FIG. 1A is a top view of a semiconductor element according to Embodiment 1;

FIG. 1B is a top view of two stacked semiconductor elements of FIG. 1A which are shifted to each other;

FIG. 1C is a sectional elevation view of a stacked semiconductor device in which a plurality of semiconductor elements shown in FIG. 1A are mounted in a stacked form;

FIG. 2A is a sectional elevation view of a stacked semiconductor device according to Embodiment 2;

FIG. 2B is a top view of a semiconductor element constituting the stacked semiconductor device shown in FIG. 2A;

FIG. 3A is a sectional elevation view of a semiconductor element according to Embodiment 3;

FIG. 3B is a sectional elevation view of a stacked semiconductor device in which a plurality of semiconductor elements shown in FIG. 3A are mounted in a stacked form;

FIG. 4A is a top view of a conventional semiconductor element;

FIG. 4B is a sectional elevation view of a stacked semiconductor device in which a plurality of semiconductor elements shown in FIG. 4A are mounted in a stacked form; and

FIG. 4C is a sectional elevation view of the semiconductor element shown in FIG. 4A.

### DETAILED DESCRIPTION OF THE PREFERRED EMBODIMENTS

Hereinafter, embodiments of the present invention will be specifically described.

(Embodiment 1)

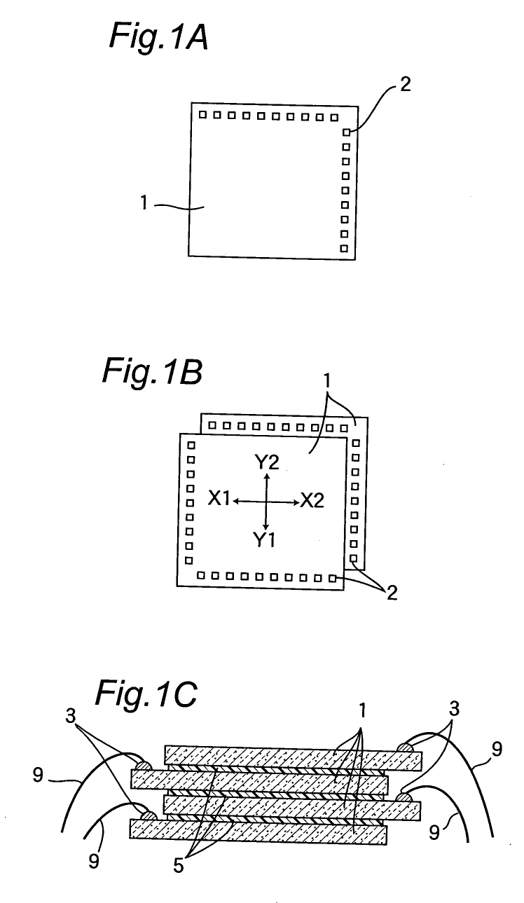

FIGS. 1A to 1C show a stacked semiconductor device according to Embodiment 1 of the present invention, in which four same-size semiconductor elements are mounted in a stacked form. In the device, the surfaces with electrode pads of the semiconductor elements are oriented in the same direction (upward). As shown in FIG. 1A, in the stacked semiconductor device, on one rectangular or square surface (upper surface) of a semiconductor element 1, a plurality of electrode pads 2 (i.e. wiring pads) are arranged near two adjacent sides in the four sides of the rectangular surface, the electrode pads 2 being lined up along the corresponding side.

As shown in FIG. 1B, two semiconductor elements 1, which are adjacent to each other in the stacking direction, that is, in the direction orthogonal to the rectangular surfaces of the semiconductor elements 1, are arranged so as to be shifted to each other in the X1-X2 direction and the Y1-Y2 direction, both of the directions being parallel to the rectangular surfaces of the semiconductor elements 1. The two semiconductor elements 1 are arranged in such a manner that the electrode pads 2 of each semiconductor element 1 do not overlap with the other semiconductor element 1 when viewed from the upper side, that is, when viewed from the direction orthogonal to the rectangular surfaces of the semiconductor elements 1.

As shown in FIG. 1C, a wire-connecting portion 3 for connecting each electrode pad 2 (see FIG. 1B) with a wire 9 is provided on each electrode pad 2. The semiconductor elements 1 adjacent to each other in the stacking direction are directly joined to each other using a die bonding material 5 without using any dummy element. Therefore, it is possible to sufficiently decrease the whole height or thickness of the stacked semiconductor device. Because it is not necessary to form a step at the peripheral portion of the semiconductor element differently from the case of the stacked semiconductor device disclosed in Japanese Laid-Open Patent Publication No. 6-244360, the fabrication process thereof is simplified. Furthermore, because a thin semiconductor element 1 can be used, it is possible to further decrease the height or thickness of the stacked semiconductor device.

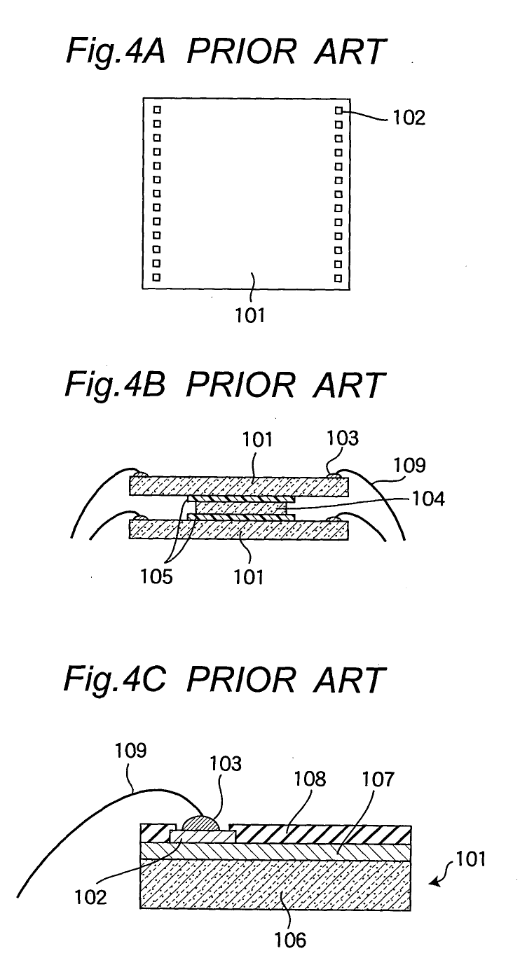

Although not illustrated, each of the semiconductor elements 1 has such a structure that a wiring layer and a silicon-nitride film are stacked in turn on a silicon substrate as same as the conventional semiconductor element 101 shown in FIG. 4C. The lower surface of each electrode pad 2 is connected to the wiring layer while the upper surface of each electrode pad 2 is exposed to the outside.

As apparent from FIG. 1C, in the stacked semiconductor device, there is nothing above each of the wire-connecting portions 3 or each of the electrode pads 2 for two upper-side semiconductor elements 1. Therefore, it is possible to easily perform wire connection, that is, easily connect the wires 9 to the electrode pads 2. Moreover, for two lower-side semiconductor elements 1, a space having a height corresponding to the total thickness of one semiconductor element 1 and two die-bonding materials 5 is present above the wire-connecting portions 3 or the electrode pads 2. In consequence, it is possible to smoothly perform wire connection or connect the wires 9 to the electrode pads 2.

As described above, in the stacked semiconductor device according to Embodiment 1, it is possible to secure a space for performing wire connection by arranging wiring pads 2 of each of the semiconductor elements 1 near two adjacent sides (their ends are connected to each other) on the rectangular or square surface of the semiconductor element 1. Therefore, it is possible to join semiconductor elements 1 to each other using only the die-bonding material 5 without using any dummy element and achieve a thin stacked semiconductor device. Moreover, it is possible to increase the number of the electrode pads 2, thereby easily increase functions of the stacked semiconductor device compared to the case of arranging the electrode pads 2 only near one side on the surface of each of the semiconductor elements 1.

(Embodiment 2)

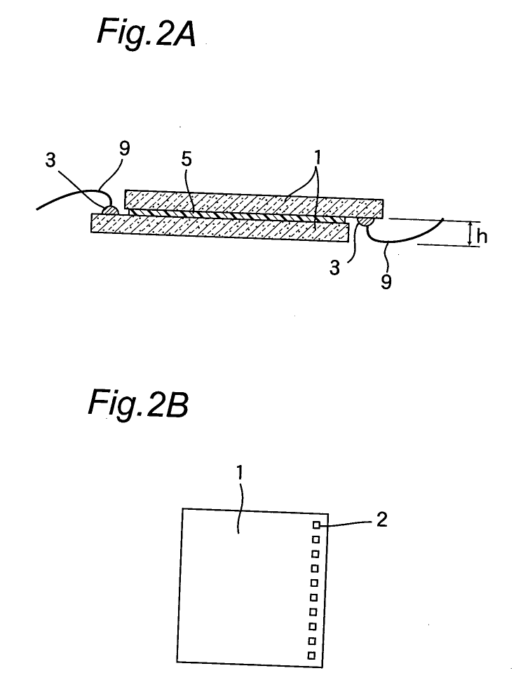

Hereinafter, Embodiment 2 of the present invention will be described with reference to FIGS. 2A and 2B. In FIGS. 2A and 2B, members common with members in FIGS. 1A to 1C are provided with the same reference numbers as those in FIGS. 1A to 1C. FIGS. 2A and 2B show a stacked semiconductor device in which two same-size semiconductor elements are mounted in a stacked form in such a manner that the surfaces with electrode pads of the semiconductor elements are faced to each other. Both of the semiconductor elements 1 are directly joined to each other using a die-bonding material 5. As shown in FIG. 2B, in the stacked semiconductor device, on one rectangular or square surface of each of semiconductor elements 1, a plurality of electrode pads 2 (i.e. wiring pads) are lined up along one side of the rectangular or square surface near the side.

As shown in FIG. 2A, both of the semiconductor elements 1 are arranged so as to be shifted to each other in the direction orthogonal to the arrangement of the electrode pads 2 and parallel with the surfaces of the semiconductor elements 1 in such a manner that the electrode pads 2 of each of the semiconductor elements 1 do not overlap with the other semiconductor element 1. As apparent from FIG. 2A, in the stacked semiconductor device, there is nothing above the electrode pads 2 for the lower-side semiconductor element 1. Therefore, it is possible to easily perform wire connection or connect the wires 9 to the electrode pads 2. Moreover, for the upper-side semiconductor element 1, there exists at least a space having the height h corresponding to the total thickness of one semiconductor element 1 and one die-bonding material 5 below the electrode pads 2. Therefore, it is possible to smoothly perform wire connection or connect the wires 9 to the electrode pads 2.

As described above, in the stacked semiconductor device according to Embodiment 2 also, because the semiconductor elements 1 are directly joined to each other using the die-bonding material 5 without using any dummy element, it is possible to sufficiently decrease the whole height or thickness of the stacked semiconductor device. Moreover, because it is not necessary to form a step on the peripheral portion of each of the semiconductor elements 1, the fabrication process thereof is simplified and it is possible to use thinner semiconductor elements 1.

(Embodiment 3)

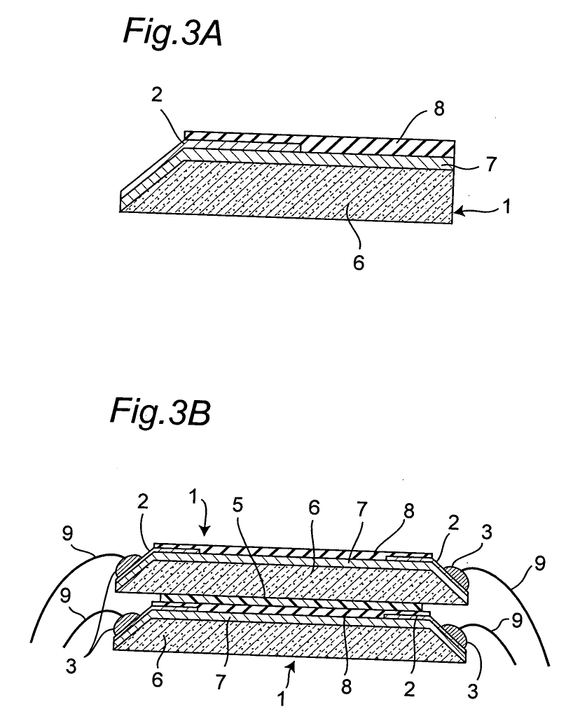

Hereinafter, Embodiment 3 of the present invention will be described with reference to FIGS. 3A and 3B. In FIGS. 3A and 3B, members common with members in FIGS. 1A to 1C are provided with the same reference numbers as those in FIGS. 1A to 1C. FIGS. 3A and 3B show a stacked semiconductor device in which two same-size semiconductor elements are mounted in a stacked form in such a manner that corresponding surfaces of the semiconductor elements 1 are oriented in the same direction.

As shown in FIGS. 3A and 3B, in the stacked semiconductor device, each of semiconductor elements 1 has such a structure that a wiring layer 7 and a silicon-nitride film 8 (protective film) are stacked in turn on a silicon substrate 6 (i.e. Si substrate). Moreover, the side surface of the silicon substrate 6 is slanted (i.e. angled) for the horizontal surfaces (upper and lower surfaces) of the silicon substrate 6. In the device, the wiring layer 7 is formed so as to cover the horizontal upper surface and slanted side surface of the silicon substrate 6. Electrode pads 2 are provided on a part of the horizontal upper surface and the slanted side surface of the wiring layer 7. The silicon-nitride film 8 covers the electrode pads 2 and wiring layer 7 at a portion corresponding to the horizontal upper surface of the silicon substrate 6.

The lower surface of the upper-side semiconductor element 1 (i.e. lower surface of the silicon substrate 6) and the upper surface of the lower-side semiconductor element 1 (upper surface of the silicon-nitride film 8) are directly joined to each other using a die-bonding material 5 in such a manner that the corresponding surfaces are oriented in the same direction. Moreover, wire-connecting portions 3 are formed on the electrode pads 2 at the slanted side surfaces of the semiconductor elements 1.

As shown in FIG. 4C again, in the conventional semiconductor element 101, various wiring layers 107 or film layers 107 are formed on the silicon substrate 106. After that, electrode pads 102 composed of aluminum (Al) wiring layers are formed on the upper surface of the semiconductor element 101, and then a silicon-nitride film 108 (protective film) is formed.

The process for fabricating the semiconductor element 1 according to Embodiment 3 is fundamentally as same as that of the above-mentioned conventional semiconductor element 101. However, in the case of Embodiment 3, the side surface of the silicon substrate 6 is slanted (angled) as shown in FIG. 3A to form various wiring layers 7 or film layers 7 on the silicon substrate 6. After that, the electrode pads 2 are provided on the slanted side surface of the semiconductor element 1. Then, the silicon-nitride film 8 is formed.

As apparent from FIG. 3B, because the electrode pads 2 are disposed on the slanted side surface of each of the semiconductor elements 1, it is not necessary to form a space for performing wire connection or connecting the wires 9 to the electrode pads 2 above the electrode pads 2. Therefore, it is possible to stack the semiconductor elements 1 only by means of the die-bonding materials 5 without using any dummy element. Thus, it is possible to decrease the whole height or thickness of the stacked semiconductor device and achieve a thinner stacked semiconductor device.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

What is claimed is:

1. A stacked semiconductor device comprising:
a plurality of semiconductor elements mounted on said device in a stacked form, each of said semiconductor elements having a quadrangular surface; and
a plurality of electrode pads provided on each of said quadrangular surfaces of said semiconductor elements, wherein
said electrode pads provided on each of said quadrangular surfaces are intensively arranged near two sides adjacent to each other, of said quadrangular surface, while
said semiconductor elements, which are adjacent to each other in a direction that said semiconductor elements are stacked, are arranged so as to be shifted in a direction parallel with said quadrangular surfaces in such a manner that said electrode pads provided on each of said semiconductor elements adjacent to each other do not overlap with the other semiconductor element when viewed from a direction orthogonal to said quadrangular surfaces.

2. A stacked semiconductor device comprising:
two semiconductor elements mounted on said device in a stacked form, each of said semiconductor elements having a quadrangular surface; and
a plurality of electrode pads provided on each of said quadrangular surfaces of said semiconductor elements, wherein
said electrode pads provided on each of said quadrangular surfaces are intensively arranged near one side of said quadrangular surface, while
said semiconductor elements are arranged so as to be shifted in a direction parallel with said quadrangular surfaces in such a manner that said quadrangular surface of one of said semiconductor elements is faced to said quadrangular surface of the other semiconductor element and said electrode pads provided on each of said semiconductor elements do not overlap with the other semiconductor element when viewed from a direction orthogonal to said quadrangular surfaces.

3. A stacked semiconductor device comprising:
a plurality of semiconductor elements mounted on said device in a stacked form; and
a plurality of electrode pads provided on each of said semiconductor elements, wherein
said electrode pads provided on each of said semiconductor element are arranged on a side surface of said semiconductor element.

4. The stacked semiconductor device according to claim 3, wherein each of said side surfaces is slanted for a horizontal surface of said semiconductor element.

5. The stacked semiconductor device according to claim 1, wherein
said semiconductor elements, which are adjacent to each other in the direction that said semiconductor elements are stacked, are directly joined to each other by means of an adhesive.

6. The stacked semiconductor device according to claim 2, wherein
said semiconductor elements are directly joined to each other by means of an adhesive.

7. The stacked semiconductor device according to claim 3, wherein
said semiconductor elements, which are adjacent to each other in the direction that said semiconductor elements are stacked, are directly joined to each other by means of an adhesive.

8. The stacked semiconductor device according to claim 4, wherein
said semiconductor elements, which are adjacent to each other in the direction that said semiconductor elements are stacked, are directly joined to each other by means of an adhesive.
